(19) United States
(12) Patent Application Publication
(10) Pub. No.: US 2026/0260901 A1
(43) Pub. Date: Sep. 3, 2026

(54) COMPOSITE CURRENT COLLECTOR, AND PREPARATION METHOD THEREFOR AND USE THEREOF

(71) Applicant: YANGZHOU NANOPORE INNOVATIVE MATERIALS TECHNOLOGY LTD, Yangzhou (CN)

(72) Inventors: Ke LIU, Yangzhou (CN); Zhenglin LI, Yangzhou (CN); Chenghao WANG, Yangzhou (CN); Yahong WU, Yangzhou (CN); Xuefa LI, Yangzhou (CN); Guoping ZHANG, Yangzhou (CN)

(21) Appl. No.: 18/878,623

(22) PCT Filed: Jun. 20, 2023
(86) PCT No.: PCT/CN2023/101227

§ 371 Date: Dec. 23, 2024

(30) Foreign Application Priority Data
Jun. 24, 2022 (CN) 202210723155.2
Sep. 2, 2022 (WO) PCT/CN2022/116829

(51) Int. Cl. H01M 4/66

(52) U.S. Cl. CPC H01M 4/663; H01M 4/667

(57) ABSTRACT

A composite current collector, and a preparation method therefor and a use thereof, relating to the technical field of new materials. The composite current collector comprises a polymer substrate layer and a diamond-like carbon layer arranged on at least one surface of the polymer substrate layer. A metal layer is further arranged on the side of the diamond-like carbon layer away from the polymer substrate layer. In the diamond-like carbon layer, the proportion of Cₛₚ₃-Cₛₚ₃ bonds is 40%-88%. The diamond-like carbon layer is compounded between the metal layer and the polymer substrate layer, and the proportion of different types of C—C bonds in the diamond-like carbon layer is controlled, so that the hardness of the composite current collector can be effectively improved, and excessive negative effects on the conductivity and flexibility of the composite current collector can be avoided. In addition, a conventional pure metal foil is replaced by a polymer substrate layer compounded with a metal layer, so that the density of a current collector can be reduced, and when the prepared composite current collector is used for a secondary battery, the energy density of the secondary battery can be effectively improved.

### TECHNICAL FIELD

The present application relates to the technical field of secondary batteries, and in particular relates to a composite current collector, a preparation method therefor, and an application thereof.

### BACKGROUND

In recent years, the secondary power battery has been developed rapidly, and its main components comprise a positive electrode, a negative electrode, a separator, an electrolyte, and a housing, wherein the positive electrode and negative electrode comprise a positive electrode active material, a negative electrode active material, and a current collector. The current collector is mainly used to collect and output the current generated by the active material and input the electrode current to the active material. The current collector is usually required to have high purity, good conductivity, good stability, and high mechanical strength.

In the art, the metal foil is the main raw material used for the current collectors, and the metal foil is usually prepared by calendering method or electrolysis method. In the calendering method, the metal foil is prepared by repeated pressing, the thickness is difficult to be thin, the uniformity is poor, and the requirements for equipment are high; in the electrolysis method, the metal foil is formed by electrolyzing a salt solution containing the required metal and crystallizes on the surface of the electrode, but the metal layer formed by crystallization is usually relatively loose; therefore, this preparation method directly leads to the poor strength of the obtained metal foil. Although the thickness is sufficiently thin, the low strength results in easy wrinkling during the use. In addition, the use of the pure metal foil for the current collector also has the problem of heavy weight, which easily leads to a decrease in the energy density of the battery.

### SUMMARY

In view of the problems above, it is necessary to provide a composite current collector, a preparation method therefor and an application thereof, and the composite current collector adopts a polymer film to replace a part of the metal foil in the conventional current collector. Therefore, the energy density of the battery can be effectively improved, and the composite current collector has both a thin thickness and a high strength, and is not easy to be wrinkled during use.

In a first aspect, the present application provides a composite current collector, which comprises a polymer substrate layer, a diamond-like carbon layer, and a metal layer; the diamond-like carbon layer is arranged on at least one surface of the polymer substrate layer, and the metal layer is arranged on a side of the diamond-like carbon layer away from the polymer substrate layer.

In the diamond-like carbon layer, a proportion of Cₛₚ₃-Cₛₚ₃ bonds is 40%-88%, preferably 60%-78%.

In some embodiments, the diamond-like carbon layers are arranged on both surfaces of the polymer substrate layer, and a sum of thicknesses of the diamond-like carbon layers constitutes 12%-50% of a thickness of the composite current collector.

In some embodiments, a raw material of the polymer substrate layer comprises one or more selected from polyethylene terephthalate, polyethylene, polypropylene, and polymethylpentene.

In some embodiments, a raw material of the metal layer comprises an elementary substance aluminum or an elementary substance copper.

In a second aspect, the present application provides a preparation method of the composite current collector as described in one or more of the aforementioned embodiments, and the preparation method comprises the following steps:
providing the polymer substrate layer; depositing the diamond-like carbon layer on a surface of the polymer substrate layer; and depositing the metal layer on a surface of the diamond-like carbon layer.

In some embodiments, the preparation method further comprises a step of treating at 30° C.-80° C. for 1 h-6 h after depositing the diamond-like carbon layer on a surface of the polymer substrate layer and before depositing the metal layer on a surface of the diamond-like carbon layer.

In some embodiments, the diamond-like carbon layer is deposited on the surface of the polymer substrate layer by ion beam deposition, wherein processing parameters of the ion beam deposition comprise: an accelerating voltage of 20 kV-80 kV, and a beam intensity of 10 mA-100 mA.

In some embodiments, a method of depositing the metal layer on a surface of the diamond-like carbon layer comprises magnetron sputtering vacuum deposition and/or electroplating;
wherein the processing parameters of the magnetron sputtering vacuum deposition comprise: a voltage of 6 kV-8 kV and a vacuum degree of 0.001 Pa-0.5 Pa; and
wherein the processing parameters of the electroplating comprise: an electrolyte solution concentration of 60 g/L-80 g/L and a current density of 1 A/dm²-3 A/dm².

In a third aspect, the present application provides a secondary battery comprising the composite current collector as described in one or more of the aforementioned embodiments.

In a fourth aspect, the present application provides an electrical device comprising the aforementioned secondary battery.

By arranging a diamond-like carbon layer between the metal layer and the polymer substrate layer, and controlling the proportion of Cₛₚ₃-Cₛₚ₃ bonds in the diamond-like carbon layer to be 40%-88%, not only the strength of the composite current collector can be effectively improved, overcoming the shortcoming of being wrinkled in the current collector during the use in the conventional technology, but also the conductivity and flexibility of the composite current collector are not negatively impacted, which is beneficial to the winding process of the battery. In addition, the polymer substrate layer compounded with the metal layer, which is used to replace the conventional pure metal foil, can reduce the density of the current collector, and can effectively improve the energy density of a secondary battery when used therein.

### BRIEF DESCRIPTION OF DRAWINGS

FIG. 1 shows a photograph of a composite current collector prepared according to an embodiment of the present application;

FIG. 2 shows a photograph of the wrinkling phenomenon of the current collector prepared according to Comparative Example 1.

### DETAILED DESCRIPTION

In order to facilitate the understanding of the present application, a detailed description of the present application is provided below with reference to the drawings. The drawings provide preferred embodiments of the present application. However, the present application can be implemented in many different forms. However, the present application can be implemented in many different forms and is not limited to the embodiments described herein. On the contrary, the object of providing these embodiments is to provide a more thorough and comprehensive understanding of the disclosure of the present application.

In addition, terms such as “first” and “second” are used only for descriptive purposes and cannot be understood as indicating or implying relative importance or implicitly specifying the number of technical features referred to. Thus, features defined by “first” and “second” can explicitly or implicitly comprise at least one of the features. In the description of the present application, unless otherwise expressly specified, “a plurality of” means at least two, such as two, three, etc. In the description of the present application, unless otherwise expressly specified, “some” means at least one, such as one, two, etc.

Unless otherwise defined, the meaning of all technical terms and scientific terms used herein is the same as that commonly understood by those skilled in the art of the present application. The terms used herein in the specification of the present application are for the purpose of describing specific embodiments only and are not intended to limit the present application. The term ‘and/or’ as used herein comprises any and all combinations of one or more of the relevant listed items.

In the present application, the technical features described in an open manner comprise closed technical solutions consisting of the listed features, as well as opened technical solutions containing the listed features.

In the present application, for the value ranges involved, unless otherwise specified, the above value ranges are considered to be consecutive, and comprise a minimum value and a maximum value of this range as well as every value between such minimum value and such maximum value. Furthermore, when the range refers to an integer, it comprises every integer between the minimum value and the maximum value of the range. In addition, when multiple ranges are provided to describe a feature or characteristic, the ranges can be combined. In other words, unless otherwise specified, all ranges disclosed herein should be understood to comprise any and all sub-ranges subsumed therein.

The percentage content involved in the present application, unless otherwise specified, refers to a mass percentage for both solid-liquid mixing and solid-solid mixing, and a volume percentage for liquid-liquid mixing.

The percentage concentration in the present application, unless otherwise specified, refers to a final concentration. The final concentration refers to a proportion of the added ingredient in the system added with the ingredient.

The temperature parameters in the present application, unless otherwise limited, are allowed to be processed either at a certain temperature or within a certain temperature range. The treatment at a certain temperature allows the fluctuation of the temperature within the controlled accuracy of the instrument.

In a first aspect, the present application provides a composite current collector, which comprises a polymer substrate layer, a diamond-like carbon layer, and a metal layer; the diamond-like carbon layer is arranged on at least one surface of the polymer substrate layer, and the metal layer is arranged on a side of the diamond-like carbon layer away from the polymer substrate layer.

In some embodiments of the present application, in the diamond-like carbon layer, a proportion of Cₛₚ₃-Cₛₚ₃ bonds is 40%-88%.

Preferably, in the diamond-like carbon layer, the proportion of Cₛₚ₃-Cₛₚ₃ bonds is 60%-78%; optionally, in the diamond-like carbon layer, the proportion of Cₛₚ₃-Cₛₚ₃ bonds can be 45%, 50%, 55%, 60%, 65%, 70%, 75%, 80%, or 85%.

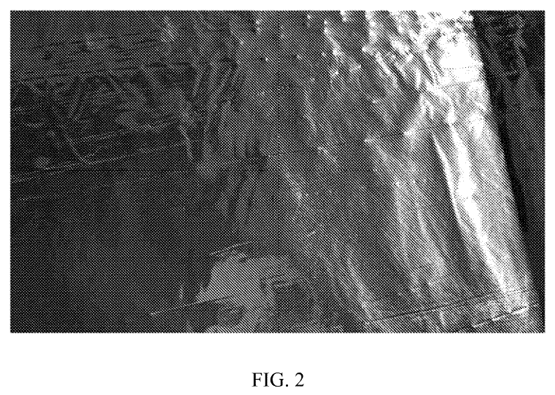

Diamond is a material with a high hardness and a high strength, and in the structure of diamond, the carbon atom shows a sp³ hybrid state; while graphite is a soft, conductive and flexible material, and in the structure of graphite, the carbon atom shows a sp² hybrid state. Diamond-like carbon has both hybrid states of diamond and graphite, so the strength, conductivity, and flexibility of the diamond-like carbon can be adjusted by controlling the proportion of C—C bonds with different hybrid states in diamond-like carbon. The inventor of the present application has found by a lot of studies that by combining a diamond-like carbon layer between the metal layer and the polymer substrate layer, and at the same time controlling the proportion of Cₛₚ₃-Cₛₚ₃ bonds in the diamond-like carbon layer to be 40%-88%, not only the strength of the composite current collector can be effectively improved, overcoming the shortcoming of being wrinkled on the current collector during the use in the conventional technology (the wrinkling phenomenon of the current collector can refer to FIG. 2 of the accompanying drawings of the specification), but also the conductivity and flexibility of the composite current collector are not negatively impacted, which is conducive to the winding process of batteries. In addition, the polymer substrate layer compounded with the metal layer, which is used to replace the conventional pure metal foil, can reduce a density of the current collector, and can effectively improve the energy density of a secondary battery when used therein.

In some embodiments, it can be understood that the diamond-like carbon layer can be doped or undoped with elements other than carbon; for example, the titanium can be doped to further release the internal stresses of the coating.

In some embodiments, the diamond-like carbon layers are arranged on both surfaces of the polymer substrate layer, and a sum of the thicknesses of the diamond-like carbon layers constitutes 12%-50% of the thickness of the composite current collector. Optionally, the sum of the thicknesses of the diamond-like carbon layers can be for example 22%-28%, or it can be 15%, 20%, 25%, 30%, 35%, 40%, or 45%. The thickness proportion of the diamond-like carbon layer in the whole composite current collector is controlled within a certain range, which can further balance the strength, toughness and conductivity of the composite current collector, so that the composite current collector is more suitable for the winding process of the secondary battery. In addition, the appropriate proportion of diamond-like carbon layer is also an important factor to avoid the decline of the energy density of the battery on the premise of satisfying the improvement of strength.

In some embodiments, a raw material of the polymer substrate layer comprises one or more selected from polyethylene terephthalate, polyethylene, polypropylene, and polymethylpentene.

The appropriate polymer material can provide a better bonding force with the diamond-like carbon layer and the metal layer, as well as a more matched toughness, so as to avoid detachment during the winding process, which can affect the conductivity of the battery.

In some embodiments, a raw material of the metal layer comprises an elementary substance aluminum or an elementary substance copper.

In a second aspect, the present application provides a preparation method for the composite current collector as described in one or more of the aforementioned embodiments, and the preparation method comprises the following steps:
providing the polymer substrate layer; depositing the diamond-like carbon layer on a surface of the polymer substrate layer; and depositing the metal layer on a surface of the diamond-like carbon layer.

In some embodiments, the diamond-like carbon layer is deposited on the surface of the polymer substrate layer by employing the physical vapor deposition technology. The physical vapor deposition technology is used for deposition, so that the polymer substrate layer and the diamond-like carbon layer have a good binding force, thus avoiding the use of binders, and significantly reducing the internal resistance of the composite current collector.

In some embodiments, the physical vapor deposition is performed at 20° C.-30° C., and preferably at room temperature of 25° C.

In some embodiments, the physical vapor deposition is ion beam deposition, wherein processing parameters of the ion beam deposition comprise: an accelerating voltage of 20 kV-80 kV, and a beam intensity of 10 mA-100 mA. When ion beam deposition is used, appropriate processing parameters can control the proportion of C—C bonds with different hybrid states in the diamond-like carbon layer within a preset range, thus balancing the strength, conductivity, and flexibility of the finished composite current collector. In addition, appropriate processing parameters also enable the temperature of the polymer substrate layer to be maintained within a suitable range during the deposition, which is helpful for the orientation formation of the molecular chains in the polymer substrate layer, and can improve the thermal shrinkage of the polymer substrate layer in the resulted composite current collector. The accelerating voltage can be, for example, 30 kV, 40 kV, 50 kV, 60 kV, or 70 kV, and the beam intensity can be, for example, 20 mA, 30 mA, 40 mA, 50 mA, 60 mA, 70 mA, 80 mA, or 90 mA.

It should be understood that the time for ion beam deposition is determined on the basis of a required thickness of the diamond-like carbon layer to be deposited, which can be, for example, 10 min, 20 min, 30 min, 40 min, 50 min, or 60 min.

With the increase of the extraction voltage and beam intensity, the energy increase of energy source creates more micro environment that is suitable for the formation of Cₛₚ₃-Cₛₚ₃ bonds, so that the proportion of Cₛₚ₃-Cₛₚ₃ bonds in the diamond-like carbon layer becomes larger.

In some embodiments, the preparation method further comprises a step of treating at 30° C.-80° C. for 1 h-6 h after depositing the diamond-like carbon layer on a surface of the polymer substrate layer and before depositing the metal layer on a surface of the diamond-like carbon layer. The semi-finished product having the deposited diamond-like carbon layer is subjected to thermal formation at a temperature of 30° C.-80° C. for 1 h-6 h, which can effectively release the internal stress of the coating, make the surface of the diamond-like coating smoother, and does not cause a negative impact such as melting or deformation on the polymer substrate layer. The thermal formation can be performed at a temperature of, for example, 40° C., 50° C., 60° C., or 70° C.; the thermal formation can be performed for a period of, for example, 2 h, 3 h, 4 h, or 5 h; preferably, the temperature of the thermal formation is 55° C.-80° C.

In some embodiments, a method of depositing the metal layer on a surface of the diamond-like carbon layer comprises magnetron sputtering vacuum deposition and/or electroplating.

Processing parameters of the magnetron sputtering vacuum deposition comprise: a voltage of 6 kV-8 kV, and a vacuum degree of 0.001 Pa-0.5 Pa; preferably, the voltage is 7 kV; preferably, the vacuum degree is 0.15 Pa-0.25 Pa.

Processing parameters of the electroplating comprise: an electrolyte solution concentration of 60 g/L-80 g/L, and a current density of 1 A/dm²-3 A/dm²; preferably, the electrolyte solution concentration is 70 g/L, and the current density of 2 A/dm².

Preferably, the metal layer is partially deposited by magnetron sputtering vacuum deposition, and then thickened by electroplating to the required thickness. By combining the two methods, the magnetron sputtering can make the diamond-like carbon layer more tightly be bonded with the metal layer, and then the electroplating is used to thicken the layer, which can reduce the cost.

In a third aspect, the present application provides a secondary battery comprising the composite current collector as described in one or more of the aforementioned embodiments.

In a fourth aspect, the present application provides an electrical device comprising the aforementioned secondary battery.

The present application is further described in detail with reference to examples and comparative examples hereinafter. To obtain experimental parameters which are not specified in the following specific examples, see the guidelines given in the present application document firstly, and also see the experimental manuals in the field or other experimental methods known in the field, or see the experimental conditions recommended by the manufacturer. It can be understood that the instruments and raw materials are relatively specific in the following examples, and should not be limited in other specific examples; the weight of the relevant components mentioned in the examples of the present application not only refers to the specific contents of the components, but also indicates the proportional relationship of each component weight. Therefore, scaling the preparation up or down in accordance with content proportions of components in the examples shall fall within the disclosed scope of the examples in the specification of the present application. Specifically, the weight mentioned in the examples in the specification of the present application can be μg, mg, g, kg, and other mass units known in the chemistry and chemical engineering fields.

### Example 1

(1) A PET (polyethylene terephthalate) film with a thickness of 4 μm was selected as a polymer substrate layer, and graphite with 4N purity was used as a target material, a cathode was triggered by a trigger to cause an arc discharge between the cathode and the anode, so that the graphite target material was evaporated into a discharge chamber, and the evaporated target material was ionized to form positive ions in the process of plasma discharge, and the positive ions passed through the anode and the porous extraction electrode to form an ion beam with a diameter of 180 mm, and then injected into the surface of the polymer substrate layer after accelerated by an accelerating voltage to form the diamond-like carbon layer with a thickness of 1 μm on one side; the above steps were repeated, and a diamond-like carbon layer with the same thickness was formed on the other side of the polymer substrate layer; the parameters of this step were set as follows: the accelerating voltage was set to 70 kV, the beam current intensity was set to 25 mA, and the deposition was performed for a period of 15 min at a temperature of 25° C.

The content of sp³ carbon in the film was quantitatively measured by using XPS; the C1s spectrum in XPS was subjected to peak resolving according to the Gaussian distribution, and the proportion of Cₛₚ₃-Cₛₚ₃ bonds was calculated by calculating the area ratio of the peaks corresponding to the sp³ carbon to all peaks; in this example, the proportion of Cₛₚ₃-Cₛₚ₃ bonds was 65%.

(2) The semi-finished product prepared in step (1) was subjected to thermal formation at 55° C. for 2 h to release the internal stress of the coating to obtain a PET-DLC substrate;

(3) Copper was prepared into a target material and fixed on the cathode, the PET-DLC substrate prepared in step (2) was placed on the anode that was exactly faced to the target surface, the system was pumped to a high vacuum and then filled with argon to maintain a vacuum degree of 0.25 Pa, and then a voltage of 7 kV was applied between the cathode and the anode, a glow discharge was generated between the two electrodes, and the positive ions generated by the discharge flew to the cathode under the action of the electric field and collided with the atoms on the surface of the copper target, the copper atoms escaping from the target by collision sputtered on the surface of PET-DLC substrate to deposit a copper layer with a thickness of 70 nm, and the above steps were repeated to form the copper layer with the same thickness at the other side, so as to obtain the PET-DLC-Cu substrate;

(4) In a plating bath containing a copper sulfate solution with a concentration of 70 g/L, the PET-DLC-Cu substrate was used as the cathode, and an elementary substance copper was used as the anode, and electroplating was performed for thickening at a current density of 2 A/dm² to obtain an electroplated copper layer with a thickness of 0.93 μm, and the above steps were repeated to form the copper layer with the same thickness at the other side, to obtain the composite current collector with a total thickness of 8 μm;

In this example, a sum of the thicknesses of the two diamond-like carbon layers constituted 25% of a total thickness of the composite current collector.

### Example 2

This example is basically the same as Example 1, and the difference is that some processing parameters in step (1) were adjusted as follows: the accelerating voltage was set to 30 kV, and the beam intensity was set to 15 mA;
in the obtained diamond-like carbon layer, the proportion of Cₛₚ₃-Cₛₚ₃ bonds was 40%.

### Example 3

This example is basically the same as Example 1, and the difference is that some processing parameters in step (1) were adjusted as follows: the accelerating voltage was set to 80 kV, and the beam intensity was set to 65 mA;
in the obtained diamond-like carbon layer, the proportion of Cₛₚ₃-Cₛₚ₃ bonds was 80%.

### Example 4

This example is basically the same as Example 1, and the difference is that some processing parameters in step (1) were adjusted as follows: the deposition was performed for a period of 9 min;
a sum of the thicknesses of the two diamond-like carbon layers constituted 12% of a total thickness of the composite current collector.

### Example 5

This example is basically the same as Example 1, and the difference is that some processing parameters in step (1) were adjusted as follows: the deposition was performed for a period of 24 min;
a sum of the thicknesses of the two diamond-like carbon layers constituted 50% of a total thickness of the composite current collector.

### Example 6

This example is basically the same as Example 1, and the difference is that some processing parameters in step (2) were adjusted as follows: the semi-finished product prepared in step (1) was subjected to thermal formation at 80° C. for 2 h.

### Example 7

This example is basically the same as Example 1, and the difference is that some processing parameters in step (2) were adjusted as follows: the semi-finished product prepared in step (1) was subjected to thermal formation at 30° C. for 2 h.

### Example 8

(1) A polypropylene film with a thickness of 4 μm was selected as a polymer substrate layer, and graphite with 4N purity was used as a target material, a cathode was triggered by a trigger to cause an arc discharge between the cathode and the anode, so that the graphite target material was evaporated into a discharge chamber, and the evaporated target material was ionized to form positive ions in the process of plasma discharge, and the positive ions passed through the anode and the porous extraction electrode to form an metal ion beam with a diameter of 180 mm, and then injected into the surface of the polymer substrate layer after accelerated by an accelerating voltage to form the diamond-like carbon layer with a thickness of 1 μm on one side, wherein the proportion of Cₛₚ₃-Cₛₚ₃ bonds was 60%; the above steps were repeated, and a diamond-like carbon layer with the same thickness was formed on the other side of the polymer substrate layer; the parameters of this step were set as follows: the accelerating voltage was set to 60 kV, the beam current intensity was set to 30 mA, and the deposition was performed for a period of 15 min at a temperature of 25° C.

(2) The semi-finished product prepared in step (1) was subjected to thermal formation at 55° C. for 6 h to release the internal stress of the coating to obtain a PP-DLC substrate.

(3) Aluminum was prepared into a target material and fixed on the cathode, the PP-DLC substrate prepared in step (2) was placed on the anode that was directly faced to the target surface, the system was pumped to a high vacuum and then filled with argon to maintain a vacuum degree of 0.15 Pa, and then a voltage of 7 kV was applied between the cathode and the anode, a glow discharge was generated between the two electrodes, and the positive ions generated by the discharge flew to the cathode under the action of the electric field and collided with the atoms on the surface of the copper target, the copper atoms escaping from the target by collision sputtered on the surface of PP-DLC substrate to deposit an aluminum layer with a thickness of 70 nm, and the above steps were repeated to form the copper layer with the same thickness at the other side, to obtain the PP-DLC-Al substrate.

(4) In a plating bath containing an ether solution of aluminum alkoxide and anhydrous aluminum trichloride with an aluminum ion concentration of 70 g/L, the PP-DLC-Al substrate was used as the cathode, and an elementary substance aluminum was used as the anode, and electroplating was performed for thickening at a current density of 2 A/dm² to obtain an electroplated aluminum layer with a thickness of 0.93 μm, and the above steps were repeated to form the aluminum layer with the same thickness at the other side, to obtain the composite current collector with a total thickness of 8 μm.

In this example, a sum of the thicknesses of the two diamond-like carbon layers constituted 25% of a total thickness of the composite current collector.

### Comparative Example 1

(1) Copper was prepared into a target material and fixed on the cathode, a PET film with a thickness of 4 μm was placed on the anode that was exactly faced to the target surface, the system was pumped to a high vacuum and then filled with argon to maintain a vacuum degree of 0.25 Pa, and then a voltage of 7 kV was applied between the cathode and the anode, a glow discharge was generated between the two electrodes, and the positive ions generated by the discharge flew to the cathode under the action of the electric field and collided with the atoms on the surface of the copper target, the copper atoms escaping from the target by collision sputtered on the surface of PET film to deposit a copper layer with a thickness of 70 nm, and the above steps were repeated to form the copper layer with the same thickness at the other side to obtain the PET-Cu substrate.

(2) In a plating bath containing a copper sulfate solution with a concentration of 70 g/L, the PET-Cu substrate was used as the cathode, and an elementary substance copper was used as the anode, and electroplating was performed for thickening at a current density of 2 A/dm² to obtain an electroplated copper layer with a thickness of 3.93 μm, and the above steps were repeated to form the copper layer with the same thickness at the other side to obtain the composite current collector with a total thickness of 8 μm.

### Comparative Example 2

This comparative example is basically the same as Example 1, and the difference is that step (2) was not comprised.

### Comparative Example 3

This comparative example is basically the same as Example 1, and the difference is that some processing parameters in step (1) were adjusted as follows: the accelerating voltage was set to 25 kV, and the beam intensity was set to 13 mA.

In the obtained diamond-like carbon layer, the proportion of Cₛₚ₃-Cₛₚ₃ bonds was 35%.

TABLE 1

| | Cₛₚ₃—Cₛₚ₃ | | | | | | | | |
|---|---|---|---|---|---|---|---|---|---|
| | bond | Thickness | | | | | | | |
| | proportion | proportion | Accel- | | | Thermal | | | |
| | in diamond- | of diamond- | erating | Beam | | formation | | | |
| | like carbon | like carbon | voltage | intensity | Deposition | temperature | Resistivity | Hardness | Deformation |
| | layer(%) | layer (%) | (kV) | (mA) | time (min) | (° C.) | (Ω · cm) | (GPa) | (mm/1 m) |
| Example 1 | 65 | 25 | 70 | 25 | 15 | 55 | 7.5 | 18 | 12 |
| Example 2 | 40 | 25 | 30 | 15 | 15 | 55 | 5.3 | 5 | 14 |
| Example 3 | 80 | 25 | 80 | 65 | 15 | 55 | 11 | 25 | 13 |
| Example 4 | 65 | 12 | 70 | 25 | 9 | 55 | 4.7 | 10 | 16 |
| Example 5 | 65 | 50 | 70 | 25 | 24 | 55 | 9 | 29 | 11 |
| Example 6 | 65 | 25 | 70 | 25 | 15 | 80 | 7.8 | 17 | 6 |
| Example 7 | 65 | 25 | 70 | 25 | 15 | 30 | 7.4 | 18 | 30 |
| Example 8 | 60 | 25 | 65 | 30 | 15 | 55 | 6 | 12 | 13 |
| Comparative | / | / | / | / | / | / | 5.1 | 0.9 | 39 |
| Example 1 | | | | | | | | | |
| Comparative | 65 | 25 | 70 | 25 | 15 | / | 13 | 17.6 | 24 |
| Example 2 | | | | | | | | | |
| Comparative | 35 | 25 | 25 | 13 | 15 | 55 | 4.8 | 2 | 16 |
| Example 3 | | | | | | | | | |

By analyzing the data in Table 1 and comparing the results of Examples 1-3 with those of Comparative Example 3, it can be seen that by adjusting the accelerating voltage and beam intensity during the deposition, the proportion of Cₛₚ₃-Cₛₚ₃ bonds in the diamond-like carbon layer could be controlled, and as the proportion was higher, the hardness of the obtained composite current collector was higher, but the resistivity was also higher, and the deformation decreased first and then increased. For the balance of performance, in some embodiments, the proportion of Cₛₚ₃-Cₛₚ₃ bonds in the diamond-like carbon layer is controlled to be within the range of 40%-88%, preferably within the range of 60%-78%.

As can be seen from the results of Examples 1, 4, and 5, as the proportion of the sum of the thicknesses of the diamond-like carbon layers in the composite current collector increased, the hardness increased, and the deformation decreased, but the resistivity also increased at the same time. For the balance of performance, in some embodiments, the proportion of the sum of the thicknesses of the diamond-like carbon layers can be within the range of 22%-28%

As can be seen from the results of Examples 1, 6, and 7, as the temperature of the thermal formation increased, the deformation decreased, and the effect on resistivity and hardness was not significant. Therefore, the temperature of the thermal formation is preferably set at 55° C.-80° C.

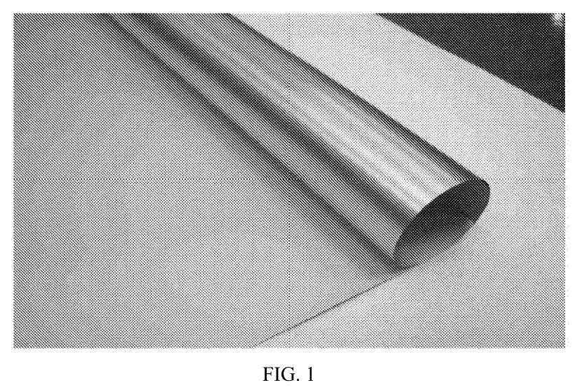

As can be seen from the comparison of the results of Example 1 and Comparative Example 1, the hardness of the current collector without the diamond-like carbon layer was very low, the deformation was very large, and hence the current collector was easily wrinkled during the use (FIG. 1).

As can be seen from the comparison of the results of Example 1 and Comparative Example 2, the composite current collector without the thermal formation had an uneven coating surface and untight interlayer bonding due to unreleased internal stresses after the deposition of the diamond-like carbon layer, resulting in increased interfacial resistance. In addition, the unreleased stress also led to an increase in deformation.

The technical features of the above examples can be combined in any manner, and for the reason of brief description, not all possible combinations of the technical features of the above examples have been described. However, as long as there is no contradiction in the combinations of these technical features, they should be considered to be recorded by this specification.

The above examples only illustrate several embodiments of the present application, which are described in details, but they are not regarded as a limitation of the protection scope of the present application. It should be noted that those skilled in the art may make various modifications and improvements without departing from the conception of the present application, which are within the protection scope of the present application. Therefore, the protection scope of the present application shall be subject to the contents of the claims, and the specification and accompanying drawings may be used to explain the content of the claims.

1. A composite current collector, comprising: a polymer substrate layer, a diamond-like carbon layer and a metal layer; wherein the diamond-like carbon layer is arranged on at least one surface of the polymer substrate layer, and the metal layer is arranged on the diamond-like carbon layer on a side away from the polymer substrate layer;
wherein in the diamond-like carbon layer, a proportion of Cₛₚ₃-Cₛₚ₃ bonds is 40%-88%.

2. The composite current collector according to claim 1, wherein the diamond-like carbon layer is arranged on both surfaces of the polymer substrate layer, and a sum of thicknesses of the diamond-like carbon layers constitutes 12%-50% of a thickness of the composite current collector.

3. The composite current collector according to claim 1, wherein a raw material of the polymer substrate layer comprises one or more selected from polyethylene terephthalate, polyethylene, polypropylene, and polymethylpentene.

4. The composite current collector according to claim 1, wherein a raw material of the metal layer comprises an elementary substance aluminum or an elementary substance copper.

5. A preparation method for the composite current collector according to claim 1, comprising the following steps:
providing the polymer substrate layer; depositing the diamond-like carbon layer on a surface of the polymer substrate layer; and
depositing the metal layer on a surface of the diamond-like carbon layer.

6. The preparation method according to claim 5, wherein the preparation method further comprises a step of treating at 30° C.-80° C. for 1 h-6 h after depositing the diamond-like carbon layer on a surface of the polymer substrate layer and before depositing the metal layer on a surface of the diamond-like carbon layer.

7. The preparation method according to claim 5, wherein the diamond-like carbon layer is deposited on the surface of the polymer substrate layer by ion beam deposition, wherein processing parameters of the ion beam deposition comprise: an accelerating voltage of 20 kV-80 kV, and a beam intensity of 10 mA-100 mA.

8. The preparation method according to claim 5, wherein a method of depositing the metal layer on a surface of the diamond-like carbon layer comprises magnetron sputtering vacuum deposition and/or electroplating;
wherein processing parameters of the magnetron sputtering vacuum deposition comprise: a voltage of 6 kV-8 kV, and a vacuum degree of 0.001 Pa-0.5 Pa; and/or
wherein processing parameters of the electroplating comprise: an electrolyte solution concentration of 60 g/L-80 g/L, and a current density of 1 A/dm²-3 A/dm².

9. A secondary battery, comprising the composite current collector according to claim 1.

10. An electrical device, comprising the secondary battery according to claim 9.
